(19) United States
(12) Patent Application Publication
(10) Pub. No.: US 2025/0226288 A1
(43) Pub. Date: Jul. 10, 2025

(54) SEMICONDUCTOR PACKAGE ASSEMBLY WITH AN INTERLAYER COOLING PATHWAY

(71) Applicant: STATS ChipPAC Pte. Ltd., Singapore (SG)

(72) Inventors: JiSeon LEE, Incheon (KR); BumRyul MAENG, Incheon (KR); HyunKyu LEE, Incheon (KR)

(21) Appl. No.: 19/008,655

(22) Filed: Jan. 3, 2025

(30) Foreign Application Priority Data
Jan. 5, 2024 (CN) 202410018082.6

(51) Int. Cl. H01L 23/46; H01L 23/433; H01L 23/538; H01L 25/00; H01L 25/11

(52) U.S. Cl. CPC H01L 23/46; H01L 23/433; H01L 23/5385; H01L 25/117; H01L 25/50; H01L 2225/1094

(57) ABSTRACT

A semiconductor package assembly comprises: a first semiconductor package comprising a first semiconductor element and a first set of conductive patterns both exposed from its front surface; an interposer mounted on the front surface of the first semiconductor package via a set of interconnect structures, wherein the interposer comprises at its back surface a second set of conductive patterns which are aligned with the first set of conductive patterns such that the first and second sets of conductive patterns are electrically connected with each other through the set of interconnect structures; a second semiconductor package mounted on a front surface of the interposer; and wherein the interposer comprises a cooling fluid input vent and a cooling fluid output vent which pass through the interposer and define a cooling fluid pathway between the interposer and the first semiconductor package.

### TECHNICAL FIELD

The present application generally relates to semiconductor technologies, and more particularly, to a semiconductor package assembly with an interlayer cooling pathway, and a method for making a semiconductor package assembly.

### BACKGROUND OF THE INVENTION

The semiconductor industry is constantly faced with complex integration challenges as consumers want their electronics to be smaller, faster and higher performance with more and more functionalities packed into a single device. In some semiconductor packages, a Package-in-Package (PiP) or Package-on-Package (PoP) process is applied, which combines two or more integrated circuit (IC) packages together. The PiP or PoP devices can more efficiently use space, and reduce lengths of signal paths between the packages. In a typical PiP or PoP device, one or more pre-molded semiconductor packages may be mounted onto another semiconductor package through an interposer or other similar structures.

However, it is noted that certain semiconductor elements such as logic circuit chips or high bandwidth memory chips in the PiP or PoP devices may generate significant heat during operation which may not be well dissipated to the external environment due to the compact package structure of the PiP or PoP devices. Therefore, a need exists for further improvement to semiconductor package assemblies with integrated semiconductor elements.

### SUMMARY OF THE INVENTION

An objective of the present application is to provide a semiconductor package assembly with improved heat dissipation.

According to an aspect of the present application, a semiconductor package assembly is disclosed. The semiconductor package assembly comprises: a first semiconductor package comprising a first semiconductor element and a first set of conductive patterns both exposed from its front surface; an interposer mounted on the front surface of the first semiconductor package via a set of interconnect structures, wherein the interposer comprises at its back surface a second set of conductive patterns which are aligned with the first set of conductive patterns such that the first and second sets of conductive patterns are electrically connected with each other through the set of interconnect structures; a second semiconductor package mounted on a front surface of the interposer; and wherein the interposer comprises a cooling fluid input vent and a cooling fluid output vent which pass through the interposer and define a cooling fluid pathway between the interposer and the first semiconductor package to allow for a fluid flow from the cooling fluid input vent to the cooling fluid output vent at least through the exposed first semiconductor element.

According to another aspect of the present application, a method for making a semiconductor package assembly is provided. The method comprises: providing a first semiconductor package, wherein the first semiconductor package comprises a first semiconductor element and a first set of conductive patterns both exposed from its front surface; attaching a set of interconnect structures on the front surface of the first semiconductor package and electrically connecting the set of interconnect structures with the first set of conductive patterns; mounting a fluid pipe on the front surface of the first semiconductor package to at least thermally couple the fluid pipe with the exposed first semiconductor element, wherein the fluid pipe comprises an inlet portion and an outlet portion extending vertically from the front surface of the first semiconductor package; mounting an interposer on the front surface of the first semiconductor package via the set of interconnect structures, wherein the interposer comprises at its back surface a second set of conductive patterns which are aligned with the first set of conductive patterns such that the first and second sets of conductive patterns are electrically connected with each other through the set of interconnect structures, and wherein the interposer comprises a cooling fluid input vent and a cooling fluid output vent to allow the inlet portion and the outlet portion of the fluid pipe to pass through the interposer; and mounting a second semiconductor package on a front surface of the interposer.

According to a further aspect of the present application, a method for making a semiconductor package assembly is provided. The method comprises: providing a first semiconductor package, wherein the first semiconductor package comprises a first semiconductor element and a first set of conductive patterns both exposed from its front surface; attaching a set of interconnect structures on the front surface of the first semiconductor package and electrically connecting the set of interconnect structures with the first set of conductive patterns; mounting an interposer on the front surface of the first semiconductor package via the set of interconnect structures, wherein the interposer comprises at its back surface a second set of conductive patterns which are aligned with the first set of conductive patterns such that the first and second sets of conductive patterns are electrically connected with each other through the set of interconnect structures, and wherein the interposer comprises a cooling fluid input vent and a cooling fluid output vent which pass through the interposer and define a cooling fluid pathway between the interposer and the first semiconductor package; and mounting a second semiconductor package on a front surface of the interposer.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1A illustrates a semiconductor package assembly according to an embodiment of the present application.

FIG. 1B illustrates an exemplary layout of a fluid pipe on a first semiconductor package of the semiconductor package assembly shown in FIG. 1A.

FIG. 2 illustrates a semiconductor package assembly according to an embodiment of the present application.

FIG. 3A illustrate a semiconductor package assembly according to an embodiment of the present application, and FIGS. 3B and 3C illustrate two examples of an interposer in the semiconductor package assembly shown in FIG. 3A.

FIGS. 4A to 4I illustrate a method for making a semiconductor package assembly according to an embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As aforementioned, conventional semiconductor package assemblies may not have a satisfactory heat dissipation performance due to their compact structure as well as significant heat generated by semiconductor elements encapsulated within the semiconductor package assemblies. To address the heat dissipation issue, the inventors of the present application have conceived an invention of incorporating a cooling pathway that passes through a semiconductor package assembly, especially through an internal space of the semiconductor package assembly to dissipate heat generated and accumulated therein. In this way, the heat dissipation performance of the semiconductor package assembly can be improved significantly.

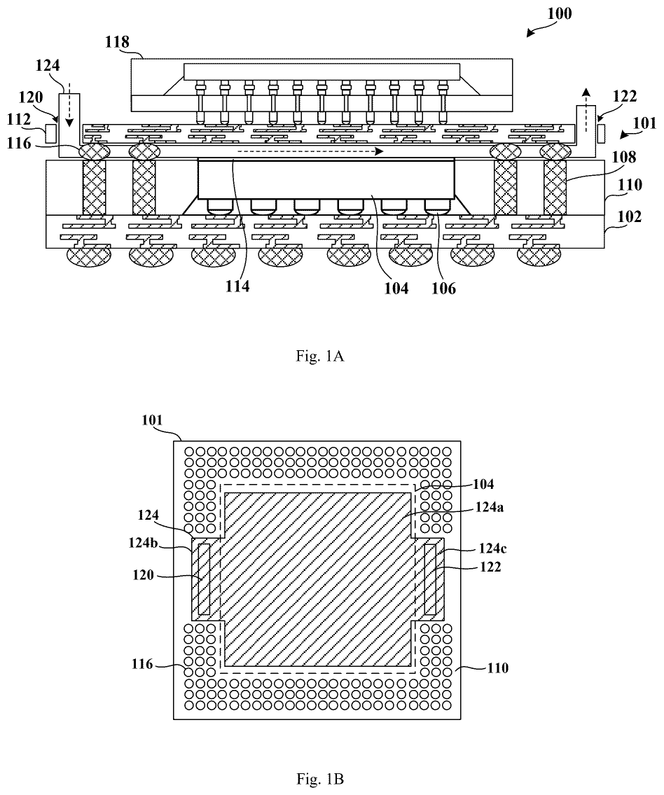

FIG. 1A illustrates a semiconductor package assembly 100 according to an embodiment of the present application. As shown in FIG. 1A, the semiconductor package assembly 100 incorporates two semiconductor packages that are stacked together through an interposer. Therefore, a semiconductor element encapsulated within a lower one of the two semiconductor packages may be embedded within the entire semiconductor package assembly 100 and relatively far away from the external environment. It should be noted that although two semiconductor packages are illustrated in FIG. 1A as an example, more semiconductor packages may be integrated within the semiconductor package assembly 100, as desired.

As shown in FIG. 1A, the semiconductor package 100 includes a first semiconductor package 101. The first semiconductor package 101 may include a first substrate 102, and at least one semiconductor element 104 mounted on the first substrate 102. In some embodiments, the semiconductor element 104 may be a semiconductor die or a smaller semiconductor package which may be mounted on a front surface of the first substrate 102 via solder bumps 106 or similar structures. Furthermore, a set of conductive structures 108 such as stacked solder bumps or copper posts may be mounted on the front surface of the first substrate 102 in parallel with the first semiconductor element 104. A mold cap 110 is formed on the first substrate 102 to encapsulate the first semiconductor element 104 and the set of conductive structures 108, and protect them from the external environment and damages. In some embodiments, the mold cap 110 may be made, partially or in all, of a polymer composite material such as epoxy resin with filler, epoxy acrylate with filler, or polymer with proper filler.

The first semiconductor package 101 has a front surface (facing upward in the direction shown in FIG. 1A) and a back surface that is opposite to the front surface. Below the back surface, solder bumps may be mounted to the first semiconductor package 101 to allow the entire semiconductor package assembly 100 to be mounted or connected to an external device when needed. On the other hand, the front surface of the first semiconductor package serves as a platform and support surface for other components of the semiconductor package assembly 100. The mold cap 110 is so formed that its front surface is a part of the front surface of the first semiconductor package 101, while the first semiconductor element 104 and the set of conductive structures 108 are exposed from the front surface of the first semiconductor package 101, as the other part of the front surface of the first semiconductor package 101. In some embodiments, the mold cap 110 may be formed with an excess amount of a molding material over the first semiconductor element 104 and the set of conductive structures 108, which may later be attenuated to some extent to expose the front surfaces of the first semiconductor element 104 and the set of conductive structures 108. With the set of conductive structures 108 exposed as a set of conductive patterns, the other components formed above the first semiconductor package 101 can be electrically coupled to the first substrate 102 and the solder bumps thereunder; with the first semiconductor element 104 exposed and not covered by the mold cap 110, a heat dissipation path is formed through the exposed front surface of the first semiconductor element 104 to allow directly dissipating heat generated by the first semiconductor element 104.

Still referring to FIG. 1A, an interposer 112 is mounted on the front surface of the first semiconductor package 101 via a set of interconnect structures 116. In particular, the interposer 112 includes at its back surface another set of conductive patterns such as contact pads, which are aligned with the set of conductive patterns on the front surface of the first semiconductor package 101. In this way, the two sets of conductive patterns can be electrically connected with each other through the set of interconnect structures 116. In some embodiments, the interposer 112 may include one or more insulating or passivation layers, one or more conductive vias formed through the insulating layers, and one or more conductive layers formed over or between the insulating layers. The conductive vias and conductive layers form together various interconnect structures in the interposer 112. Since the interposer 112 is supported on the first semiconductor package 101 by the interconnect structures 116 and thus is not in direct contact with the first semiconductor package 101, a gap between the interposer 112 and the first semiconductor package 101 is formed. A height of the gap is generally equal to a height of the set of interconnect structures 116. In some embodiments, the set of interconnect structures 116 may be solder bumps, while in some alternative embodiments, the set of interconnect structures 116 may be other interconnect components such as metal posts or e-bar modules. Besides electrically connecting the two sets of conductive patterns with each other, the interconnect structures 116 may provide mechanical support for the interposer 112 as well as components mounted thereon.

In the embodiment shown in FIG. 1A, a fluid pipe 124 is mounted between the first semiconductor package 101 and the interposer 112. The fluid pipe 124 can be in thermal contact with the exposed first semiconductor element 104, either directly or indirectly through a thermal interface material layer 114. The fluid pipe 124 forms a cooling fluid pathway between the interposer 112 and the first semiconductor package 101, which allows for a fluid flow at least through the exposed first semiconductor element 104. Therefore, heat can be dissipated from the first semiconductor element 104 at the central portion of the semiconductor package assembly 100 to the external environment by the fluid flow. In some embodiments, the fluid flow can be a liquid flow, such as a specific coolant (e.g., water), and alternatively, the fluid flow can be a gas flow such as an air flow, or a mixed gas and liquid flow such as a liquid nitrogen flow.

It can be appreciated that the fluid pipe 124 may be open to the external environment or in fluid communication with a coolant source external to the semiconductor package assembly 100, to allow for a continuous cooling process during the operation of the semiconductor package assembly 100. Therefore, a cooling fluid input vent 120 and a cooling fluid output vent 122 may be formed in the interposer 112, which can pass through the interposer 112. As such, the fluid pipe 124 can pass through the interposer 112 at the cooling fluid input vent 120 as well as at the cooling fluid output vent 122, and thus the fluid flow inside the fluid pipe 124 can flow in a direction (as shown in FIG. 1A) from the cooling fluid input vent 120 to the cooling fluid output vent 122 and carry away heat from the first semiconductor element 104 to the external environment. In some embodiments, a pump (not shown) may be in fluid communication with the fluid pipe 124 to pump into the fluid pipe 124 the coolant and cause the coolant to flow within the fluid pipe 124. For example, the pump may be disposed outside of the first semiconductor package 101 and the interposer 112. In some embodiments where a plurality of semiconductor package assemblies that are similar as the semiconductor package assembly 100 shown in FIG. 1A may be mounted in an electronic system, and accordingly, at least a portion of the fluid pipes of these semiconductor package assemblies may all be coupled to a pump and share the flow driving capability of the pump. Furthermore, besides the exposed front surface of the first semiconductor element 104, the fluid pipe 124 may extend along certain other regions of the front surface of the first semiconductor package 101, to absorb heat generated or accumulated in these regions. For example, the fluid pipe 124 may be adjacent to or in proximity to the solder bumps 116, and thus can draw heat from the solder bumps 116.

In some embodiments, the fluid pipe 124 is formed of a metal material or an alloy, which has a good thermal conductivity and is suitable for heat dissipation. It can be appreciated that the fluid pipe 124 should be electrically isolated from the solder bumps 116, to avoid undesired electrical connection between the solder bumps 116 and other conductive structures. For example, a buffer layer of an insulating material may be filled between the solder bumps 116 and the fluid pipe 124, and/or between the fluid pipe 124 and other contact pads on a back surface of the interposer 112. In some other embodiments, the fluid pipe 124 may be made of other materials with a good thermal conductivity.

As the first semiconductor element 104 may have a square or rectangular layout, the fluid pipe 124 may preferably have a similar layout. In some embodiments, the fluid pipe 124 may include a plurality of branches extending between the cooling fluid input vent 120 and the cooling fluid output vent 122, to increase its contact area with the first semiconductor element 104. In some alternative embodiments, the fluid pipe 124 may have a zigzag shape which meanders along the front surface of the first semiconductor package 101. It can be appreciated that the fluid pipe 124 may take other suitable shapes to increase its contact area with the first semiconductor package 101, or especially with the first semiconductor element 104.

FIG. 1B illustrates an exemplary layout of the fluid pipe 124 on the first semiconductor package 101 of the semiconductor package assembly 100 shown in FIG. 1A. As shown in FIG. 1B, the front surface of the first semiconductor element 104 is exposed and not covered by the mold cap 110 of the first semiconductor package 101. The fluid pipe 124 has a central portion 124a which is substantially overlapping with the exposed front surface of the first semiconductor element 104 to absorb heat therefrom. Furthermore, the fluid pipe 124 has an inlet portion 124b upstream of the central portion 124a to receive a coolant and an outlet portion 124c downstream of the central portion 124a to discharge the coolant from the central portion 124a to dissipate heat to the external, e.g., to a coolant pool or tank. As mentioned above, the central portion 124a may take other shapes such as a branched shape, a zigzag shape or a spiral shape. Furthermore, the solder bumps 116 which are mounted on the first semiconductor package 101 may be arranged around the first semiconductor element 104, and thus may not be in direct contact with the fluid pipe 124.

Referring back to FIG. 1A, a second semiconductor package 118 is further mounted on a front surface of the interposer 112, to increase the integration level of the entire semiconductor package assembly 100. The second semiconductor package 118 may have a second substrate and a second semiconductor element mounted on the second substrate, similar as the configuration and structure of the first semiconductor package 101. However, with the fluid pipe 124 mounted between the interposer 112 and the first semiconductor package 101 which introduces a separate heat dissipation path that extends into the inside of the semiconductor package assembly 100, the second semiconductor package 118 stacked over the first semiconductor package 101 may not significantly affect the heat dissipation performance of the semiconductor package assembly 100. Furthermore, although not shown in FIG. 1A, an additional mold cap may be formed on the first semiconductor package 101 or on the interposer 112, to encapsulate the respective components formed thereon. The additional mold cap may not block the fluid passage within the fluid pipe 124, and thus may not affect the heat dissipation through the fluid pipe 124.

In the embodiment shown in FIG. 1A, the second semiconductor package 118 includes a second semiconductor element such as a semiconductor die or smaller semiconductor package mounted on a second substrate, and the second semiconductor element is away from the first semiconductor element 104 of the first semiconductor package 101. In some alternative embodiments, especially when three or more semiconductor packages are stacked together, the second semiconductor package may be mounted on the interposer in a similar way as the first semiconductor package, and the second semiconductor element may also be facing towards the interposer from the front surface of the interposer. That is, the two semiconductor packages may be mounted substantially symmetrically with respect to the interposer. In that case, the fluid pipe may also extend between the interposer and the second semiconductor package for dissipating heat generated by the second semiconductor element. Optionally, a separated fluid pipe may be mounted on the front surface of the interposer for the second semiconductor package.

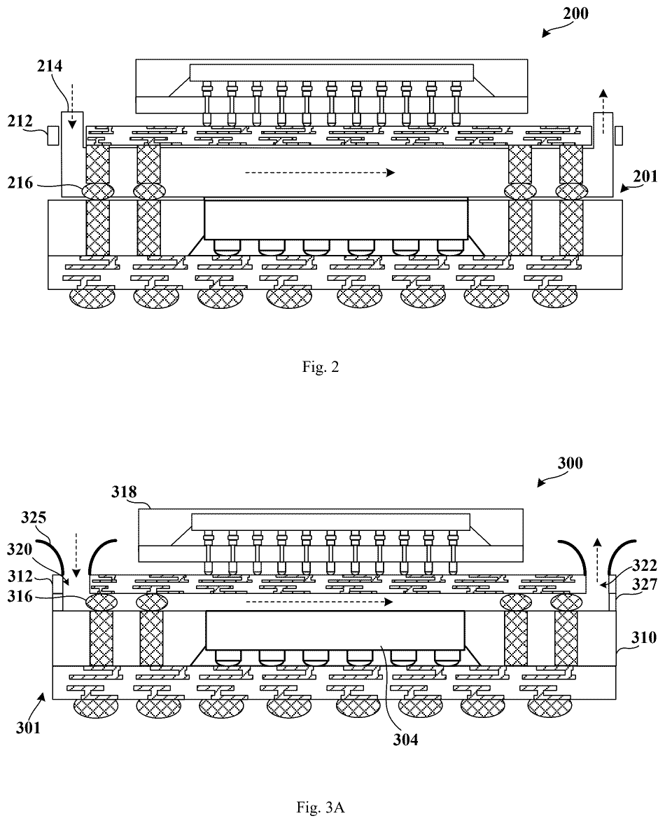

FIG. 2 illustrates a semiconductor package assembly 200 according to an embodiment of the present application. As shown in FIG. 2, the structure of the semiconductor package assembly 200 is similar to that of the semiconductor package assembly 100 shown in FIG. 1A, differing only in the interconnect structures 216. Each of the interconnect structures 216 between an interposer 212 and a first semiconductor package 201 includes a combination of a solder ball and a metal post such as copper post. Since the metal post may generally have a greater height than the solder ball, the height of the interconnect structures 216 can be increased, thus providing for more space for receiving a fluid pipe 214 which is also mounted between the interposer 212 and the first semiconductor package 201.

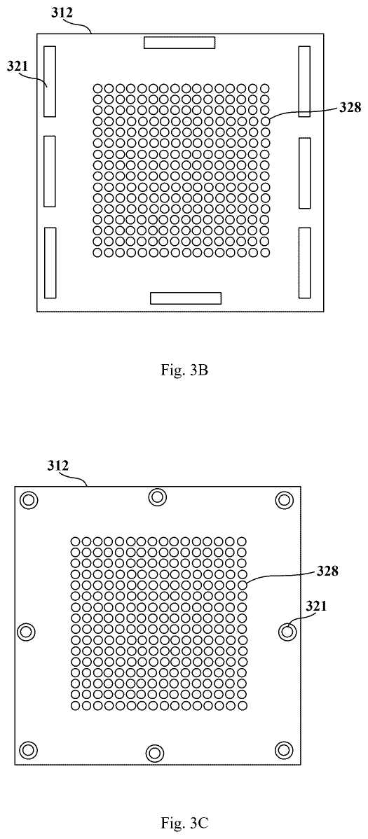

FIG. 3A illustrate a semiconductor package assembly 300 according to an embodiment of the present application, and FIGS. 3B and 3C illustrate two examples of an interposer in the semiconductor package assembly 300 shown in FIG. 3A.

As shown in FIG. 3A, the semiconductor package assembly 300 includes a first semiconductor package 301 and a second semiconductor package 318, which are connected with each other via an interposer 312 and a set of interconnect structures 316. The set of interconnect structure 316 elevates the interposer 312 and creates a space between the interposer 312 and a front surface of the first semiconductor package 301, which can be used for heat dissipation. For example, air may be introduced from the external environment into the space under the interposer 312 through a cooling fluid input vent 320. In this way, air can bring heat generated by the first semiconductor package 301, especially by a first semiconductor element 304 exposed from the front surface of the semiconductor package 301, out of the semiconductor package assembly 300, for example, through a cooling fluid output vent 322 which also passes through the interposer 312. As such, the cooling fluid input vent 320 and the cooling fluid output vent 322 define together a cooling fluid pathway between the interposer 312 and the first semiconductor package 301 to allow for a fluid flow from the cooling fluid input vent 320 to the cooling fluid output vent 322.

As shown in FIGS. 3B and 3C, multiple vents 321 may be formed at or adjacent to the periphery of the interposer 312, which may pass through the interposer 312. In operation, some of the vents 321 may function as the cooling fluid input vent(s) while the others may function as the cooling fluid output vent(s), depending on the direction of air flow(s) in the space defined by the interposer 312 and the first semiconductor package 301. In some preferred embodiments, the vents 321 may be around the first semiconductor element to ensure that air flows can pass through the front surface of the first semiconductor element. Solder bumps 328 are formed on the front surface of the interposer 312 and at its central portion, such that a second semiconductor package (not shown) can be mounted on the interposer 312 through the solder bumps 328.

In some embodiments, a fan (not shown) may be mounted on the front surface of the interposer 312 and at the cooling fluid input vent 320 to blow air into the cooling fluid pathway under the interposer 312. The improved air flow within the fluid pathway can enhance heat dissipation from the first semiconductor package. Referring back to FIG. 3A, in some embodiments, a spacer or a frame 327 may be formed between the interposer 312 and the first semiconductor package 301, or particularly, a mold cap 310 of the first semiconductor package 301. The frame 301 may be formed at or adjacent to the periphery of the interposer 312, and may generally seal the space under the interposer 312 from its periphery. In this way, air blown into the cooling fluid pathway may not leak to the outside at the periphery of the interposer 312, and thus can generally pass through the exposed surface of the first semiconductor element 304 and improve the efficiency of heat dissipation. In some embodiments, a flared access or port 325 may be disposed on the front surface of the interposer 312, at the cooling fluid input vent 320, or further at the cooling fluid output vent 322, to guide the air flow through these vents.

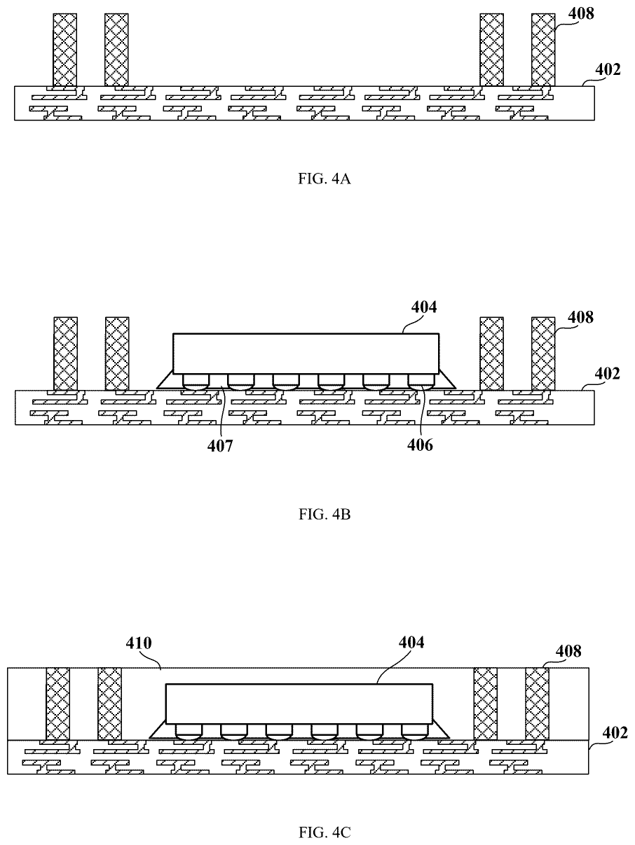

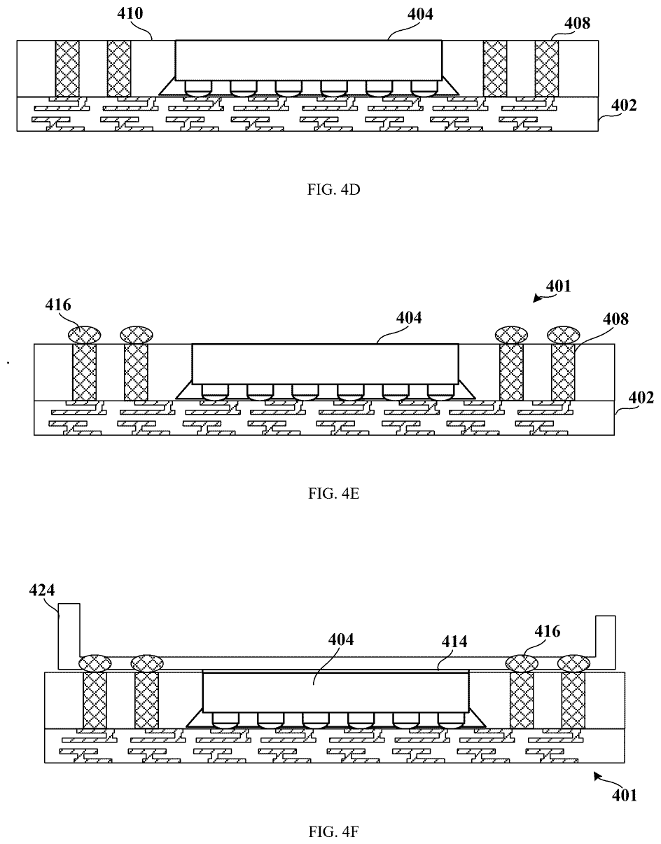

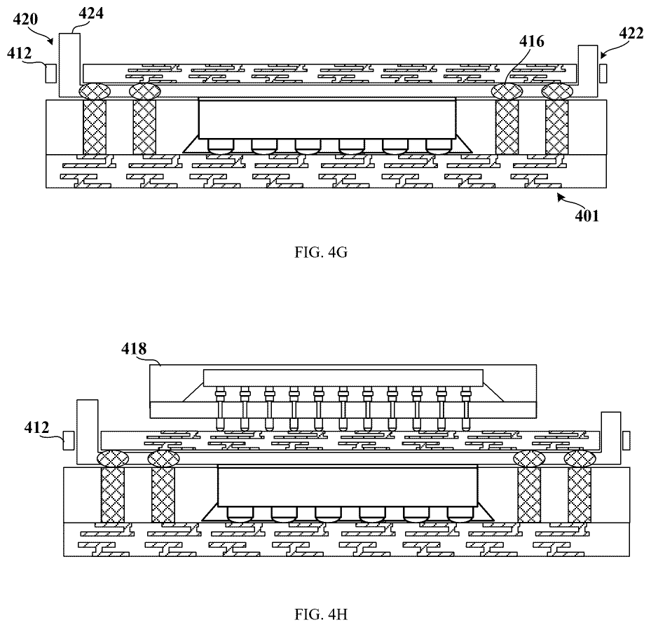

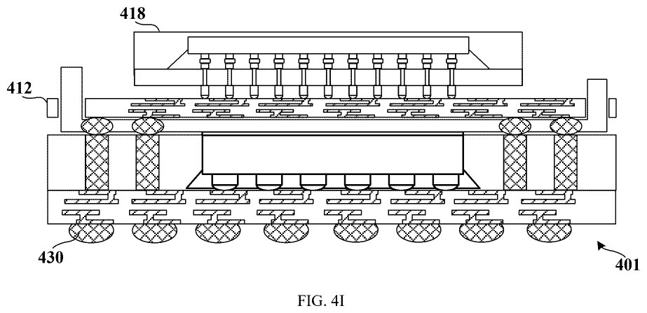

FIGS. 4A to 4I illustrate a method for making a semiconductor package assembly according to an embodiment of the present application. The method may be used to make the semiconductor package assembly 100 shown in FIG. 1A, and may be used to make the semiconductor package assembly 200 shown in FIG. 2 or the semiconductor package assembly 300 shown in FIG. 3A with some modifications.

As shown in FIG. 4A, a first substrate 402 is provided, and a set of conductive structures 408 such as metal posts may be mounted on a front surface of the first substrate 402. The conductive structures 408 may be aligned with and connected to a set of conductive patterns (not shown) on the first substrate 402 for electrical connection.

Next, as shown in FIG. 4B, a first semiconductor element 404 is mounted onto the first substrate 402 via solder bumps 406. In some embodiments, an underfill material 407 may be filled between the first semiconductor element 404 and the first substrate 402 and around the solder bumps 406, to enhance the attachment of the first semiconductor element 404 to the first substrate 402. The first semiconductor element 404 may have a height equal to or smaller than that of the conductive structures 408. Next, a mold cap 410 may be formed on the first substrate 402 to encapsulate the first semiconductor element 404 and the conductive structures 408, as shown in FIG. 4C. For example, the mold cap 410 may be formed using an injection molding process or a compression molding process. In some other embodiments, the mold cap 410 may be formed using paste printing, transfer molding, liquid encapsulant molding, vacuum lamination, spin coating, or any other suitable process.

Next, as shown in FIG. 4D, an excess portion of the molding material of the mold cap 410 that is higher than a front surface of the first semiconductor element 404 may be removed, for example, using a grinding process, to expose the front surface of the first semiconductor element 404. It can be appreciated that the higher portion of the conductive structures 408 may be removed along with the excess molding material of the mold cap 410. As such, front surfaces of the conductive structures 408 may be exposed as a set of conductive patterns, which may be later attached with a set of interconnect structures 416 such as solder bumps, as shown in FIG. 4E. The first substrate 402, the first semiconductor element 404, the conductive structures 408 and the mold cap 410 may together form a first semiconductor package 401, which will later be connected with other components.

Next, as shown in FIG. 4F, a fluid pipe 424 may be mounted on the front surface of the first semiconductor package 401 to at least thermally couple the fluid pipe 424 with the exposed first semiconductor element 404. In some embodiments, the fluid pipe 424 may be attached onto the front surface of the first semiconductor element 404 via a thermal interface material layer 414, which can improve heat transfer between the fluid pipe 424 and the first semiconductor element 404. The fluid pipe 424 may be isolated from the solder bumps 416 to avoid undesired electrical connection therebetween. The fluid pipe 424 may accommodate either liquid coolant such as water or gas coolant such as air, when the semiconductor package assembly is in operation. In some embodiments, the fluid pipe 424 may be omitted, if air is used for cooling. In that case, the step shown in FIG. 4F can be omitted. In the embodiment shown in FIG. 4F, the fluid pipe 424 may have an inlet portion and an outlet portion extending vertically from the front surface of the first semiconductor package 401, and a central portion which extends between the inlet portion and the outlet portion and is in contact with the first semiconductor package 401.

Next, as shown in FIG. 4G, an interposer 412 is mounted on the first semiconductor package 401 via the solder bumps 416. The interposer 412 may have vents 420 and 422 to allow passage of the fluid pipe 424, or particularly its inlet portion and outlet portion. The interposer 412 may have a set of conductive patterns at its back surface, which can be aligned with and connected with the solder bumps 416. In this way, the interposer 412 can be electrically coupled with the first semiconductor package 401. In some embodiments, an additional adhesive material such as a molding material may be filled between the interposer 412 and the first semiconductor package 401 to enhance their connection.

Next, as shown in FIG. 4H, a second semiconductor package 418 is mounted on a front surface of the interposer 412, for example, via solder bumps. The second semiconductor package 418 may be formed separately. Next, as shown in FIG. 4I, solder bumps 430 may be mounted on a back surface of the first semiconductor package 401 to function as an interface between the semiconductor package assembly and an external device or system. In some embodiments, a mold cap may be formed on the interposer 412 to encapsulate the interposer 412 and the second semiconductor package 418.

After the various steps shown in FIGS. 4A to 4I, the semiconductor package assembly can be obtained. In some embodiments, a pump may be mounted with the fluid pipe to be in fluid communication with the fluid pipe. The pump can be used to pump into the fluid pipe a coolant and cause the coolant to flow within the fluid pipe. In some other embodiments where no fluid pipe is mounted, a fan may be mounted on the interposer and at the cooling fluid input vent to blow air into the cooling fluid pathway within the semiconductor package assembly.

The discussion herein includes numerous illustrative figures that show various portions of a semiconductor package assembly with an interlayer cooling pathway and a method for making such semiconductor package assembly. For illustrative clarity, such figures do not show all aspects of each example semiconductor package. Any of the example packages provided herein may share any or all characteristics with any or all other packages provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A semiconductor package assembly, comprising:
a first semiconductor package comprising a first semiconductor element and a first set of conductive patterns both exposed from its front surface;
an interposer mounted on the front surface of the first semiconductor package via a set of interconnect structures, wherein the interposer comprises at its back surface a second set of conductive patterns which are aligned with the first set of conductive patterns such that the first and second sets of conductive patterns are electrically connected with each other through the set of interconnect structures;
a second semiconductor package mounted on a front surface of the interposer; and
wherein the interposer comprises a cooling fluid input vent and a cooling fluid output vent which pass through the interposer and define a cooling fluid pathway between the interposer and the first semiconductor package to allow for a fluid flow from the cooling fluid input vent to the cooling fluid output vent at least through the exposed first semiconductor element.

2. The semiconductor package assembly of claim 1, wherein the semiconductor package assembly further comprises:
a fluid pipe mounted between the first semiconductor package and the interposer, wherein the fluid pipe passes through the cooling fluid input vent and the cooling fluid output vent to form the cooling fluid pathway therein.

3. The semiconductor package assembly of claim 2, wherein the semiconductor package assembly further comprises:
a thermal interface material layer formed between the fluid pipe and the exposed first semiconductor element.

4. The semiconductor package assembly of claim 2, wherein the fluid pipe comprises a plurality of branches extending between the cooling fluid input vent and the cooling fluid output vent.

5. The semiconductor package assembly of claim 2, wherein the fluid pipe has a zigzag shape which meanders along the front surface of the first semiconductor package.

6. The semiconductor package assembly of claim 2, wherein the semiconductor package assembly further comprises:
a pump in fluid communication with the fluid pipe to pump into the fluid pipe a coolant and cause the coolant to flow within the fluid pipe.

7. The semiconductor package assembly of claim 2, wherein the fluid pipe is formed of a metal material or an alloy, and the fluid pipe is electrically isolated from the set of interconnect structures.

8. The semiconductor package assembly of claim 1, wherein the semiconductor package assembly further comprises:
a fan mounted on the front surface of the interposer and at the cooling fluid input vent to blow air into the cooling fluid pathway.

9. The semiconductor package assembly of claim 1, wherein the first semiconductor package further comprises:
a first substrate where the first semiconductor element is mounted;
a set of conductive structures mounted on the first substrate;
a mold cap encapsulating the first semiconductor element and the set of conductive structures, wherein the mold cap forms the front surface of the first semiconductor package and exposes a front surface of the first semiconductor element and front surfaces of the set of conductive structures as the first set of conductive patterns.

10. A method for making a semiconductor package assembly, the method comprising:
providing a first semiconductor package, wherein the first semiconductor package comprises a first semiconductor element and a first set of conductive patterns both exposed from its front surface;
attaching a set of interconnect structures on the front surface of the first semiconductor package and electrically connecting the set of interconnect structures with the first set of conductive patterns;
mounting a fluid pipe on the front surface of the first semiconductor package to at least thermally couple the fluid pipe with the exposed first semiconductor element, wherein the fluid pipe comprises an inlet portion and an outlet portion extending vertically from the front surface of the first semiconductor package;
mounting an interposer on the front surface of the first semiconductor package via the set of interconnect structures, wherein the interposer comprises at its back surface a second set of conductive patterns which are aligned with the first set of conductive patterns such that the first and second sets of conductive patterns are electrically connected with each other through the set of interconnect structures, and wherein the interposer comprises a cooling fluid input vent and a cooling fluid output vent to allow the inlet portion and the outlet portion of the fluid pipe to pass through the interposer; and
mounting a second semiconductor package on a front surface of the interposer.

11. The method of claim 10, wherein before mounting a fluid pipe on the front surface of the first semiconductor package, the method further comprises:
forming a thermal interface material layer on the exposed first semiconductor element.

12. The method of claim 10, wherein the method further comprises:
mounting a pump in fluid communication with the fluid pipe, and the pump is configured to pump into the fluid pipe a coolant and cause the coolant to flow within the fluid pipe.

13. A method for making a semiconductor package assembly, the method comprising:
providing a first semiconductor package, wherein the first semiconductor package comprises a first semiconductor element and a first set of conductive patterns both exposed from its front surface;
attaching a set of interconnect structures on the front surface of the first semiconductor package and electrically connecting the set of interconnect structures with the first set of conductive patterns;
mounting an interposer on the front surface of the first semiconductor package via the set of interconnect structures, wherein the interposer comprises at its back surface a second set of conductive patterns which are aligned with the first set of conductive patterns such that the first and second sets of conductive patterns are electrically connected with each other through the set of interconnect structures, and wherein the interposer comprises a cooling fluid input vent and a cooling fluid output vent which pass through the interposer and define a cooling fluid pathway between the interposer and the first semiconductor package; and
mounting a second semiconductor package on a front surface of the interposer.

14. The method of claim 13, wherein the method further comprises:
mounting a fan on the front surface of the interposer and at the cooling fluid input vent to blow air into the cooling fluid pathway.
